(19) United States
(12) Patent Application Publication
(10) Pub. No.: US 2019/0140081 A1
(43) Pub. Date: May 9, 2019

(54) TFT SUBSTRATE AND MANUFACTURING METHOD THEREOF

(71) Applicant: Wuhan China Star Optoelectronics Semiconductor Display Technology Co., LTd., Wuhan (CN)

(72) Inventor: Yun YU, Shenzhen (CN)

(21) Appl. No.: 15/968,990

(22) Filed: May 2, 2018

Related U.S. Application Data
(63) Continuation of application No. PCT/CN2018/071661, filed on Jan. 5, 2018.

(30) Foreign Application Priority Data
Nov. 6, 2017 (CN) 201711081722.4

(51) Int. Cl. H01L 29/66; H01L 29/786; H01L 27/12; H01L 29/49; H01L 21/30; H01L 21/02

(52) U.S. Cl. CPC H01L 29/66765; H01L 29/78678; H01L 27/1218; H01L 27/1266; H01L 27/3262; H01L 27/124; H01L 29/4908; H01L 21/3003; H01L 21/02672; H01L 29/78603

(57) ABSTRACT

A TFT substrate and manufacturing method thereof are provided. The method of manufacturing TFT substrate comprises providing a substrate, preparing a flexible substrate on the substrate; depositing a blocking layer on the flexible substrate; depositing a grid layer on the blocking layer, etching the grid layer for forming a grid wire, and material of the grid wire is Al; depositing a grid insulating layer on the blocking layer, the grid insulating layer covering the grid wire; forming an active layer on the grid insulting layer; depositing a layer insulating layer on the grid insulating layer, and the layer insulating layer covering the active layer; hydrotreating and activating treatment the active layer.

### RELATED APPLICATIONS

The present application is a National Phase of International Application Number PCT/CN2018/071661, filed Jan. 5, 2018, and claims the priority of China Application No. 201711081722.4, filed Nov. 6, 2017.

### FIELD OF THE DISCLOSURE

The disclosure relates to a display technical field, and more particularly to a TFT substrate and manufacturing method thereof.

### BACKGROUND

With fast development of the display technology, Organic Light Emitting Diode (OLED) has many advantageous such as light, self-luminous, wide view angle, lower driving voltage, high luminous efficiency, low power consumption, fast response, such that could widely use. Especially the flexible OLED display device has bendable and portable property so that became one of the feature mainstream display technologies. Wherein the Thin Film Transistor (TFT) which for driving OLED luminous and is one of key technology of backplane.

Therefore, how to enhance anti-bendable property of TFT substrate and achieve high resolution, high yield of OLED display device is the key research direction of currently flexible OLED display device.

### SUMMARY

A technical problem to be solved by the disclosure is to provide a TFT substrate and manufacturing method thereof with increased property of anti-bendable. Enhances resolution and yield of the flexible OLED display device which has the TFT substrate.

An objective of the disclosure is achieved by following embodiments. In particular, a method of manufacturing TFT substrate, the method comprising

providing a substrate, preparing a flexible substrate on the substrate;

depositing a blocking layer on the flexible substrate;

depositing a grid layer on the blocking layer, etching the grid layer for forming a grid wire, and material of the grid wire is Al;

depositing a grid insulating layer on the blocking layer, the grid insulating layer covering the grid wire;

forming an active layer on the grid insulting layer;

depositing a layer insulating layer on the grid insulating layer and the layer insulating layer covering the active layer;

hydrotreating and activating treatment the active layer.

In an embodiment, the grid layer is triple-layer structure, Ti/Al/Ti or Mo/Al/Mo.

In an embodiment, in the step of depositing the grid layer on the blocking layer further comprising

depositing a first Mo metal layer on the blocking layer, thickness of the first Mo metal layer is 30˜50 nm;

depositing an Al metal layer on the first Mo metal layer, thickness of the AL metal layer is 100˜120 nm;

depositing a second Mo metal layer on the AL metal layer, thickness of the second Mo metal layer is 30˜50 nm.

In an embodiment, in the step of hydrotreating and activating treatment the active layer, temperature of the hydrotreating and activating treatment is 330˜370° C., time of the hydrotreating and activating treatment is 30˜60 min.

In an embodiment, after the step of hydrotreating and activating treatment the active layer, further comprising

forming holes on the layer insulating layer, and the holes are pass through the layer insulating layer;

depositing a source and a drain on the holes, the source and the drain are electrically connecting the active layer by the holes;

peeling off the flexible substrate from the substrate.

In an embodiment, in the step of forming the active layer on the grid insulting layer, further comprising

depositing an amorphous silicon layer on the grid insulating layer;

treating the amorphous silicon layer by excimer laser to be heat source and forming the active layer.

In an embodiment, material of the grid insulating layer and layer insulating layer is SiOx or SiNx or stacked structure of SiOx and SiNx.

In an embodiment, the blocking layer is heat conductive insulation layer.

According to another aspect of the disclosure, the disclosure further provides a TFT substrate, the TFT substrate comprising a flexible substrate; a blocking layer on the flexible substrate; a grid wire on the blocking layer; a grid insulating layer covering the grid wire; an active layer on the grid insulating layer; and a layer insulating layer covering the active layer.

In an embodiment, the TFT substrate further comprises holes for passing through the layer insulating layer, a source and a drain are positioned on the holes, the source and the drain are electrically connecting to the active layer by the holes.

According to the disclosure further provides a manufacturing method of TFT substrate, sequential preparing a blocking layer, a grid wire, a grid insulating layer, and active layer and a layer insulating layer. Comparing with the material of grid wire is Mo, the material of grid wire is Al could decrease thickness or width of the grid wire such that enhances property of bendable of grid wire of the flexible display panel, while satisfy the impedance of grid wire situation. It achieves to highly resolution display.

In this disclosure, according to depositing the grid wire and the grid insulating layer firstly, and forming active layer on the grid insulating layer, then depositing the layer insulating layer on the active layer, such that upper surface and lower surface of the active layer are respectively directly connecting with the grid insulating layer and the layer insulating layer. And then, hydrotreating and activating treatment the active layer, because of the active layer is covered by the grid insulating layer and the layer insulating layer, such that hydrotreating and activating treatment will cause the H⁺ of the grid insulating layer and the layer insulating layer are diffusing to the active layer from lateral side, it enhances active effect of the active layer such that decreases defect of inside and surface of the active layer, and it enhance performance of the TFT element. In addition, because the active effect of the active layer is enhanced, it could achieve that hydrotreating and activating treatment to the active layer, and also decrease temperature of the hydrotreating and activating treatment, such that decreases conductive property effect of the grid wire by temperature of hydrotreating and activating treatment, and enhances property of TFT substrate.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a flow chart diagram of a method of manufacturing TFT substrate according to an embodiment of the disclosure;

FIG. 2 is a S100 flow chart diagram of a method of manufacturing TFT substrate according to an embodiment of the disclosure;

FIG. 3 is a S200 flow chart diagram of a method of manufacturing TFT substrate according to an embodiment of the disclosure;

FIG. 4 is a S300 flow chart diagram of a method of manufacturing TFT substrate according to an embodiment of the disclosure;

FIG. 5 is a S400 flow chart diagram of a method of manufacturing TFT substrate according to an embodiment of the disclosure;

FIG. 6 is a S500 flow chart diagram of a method of manufacturing TFT substrate according to an embodiment of the disclosure;

FIG. 7 is a S600 flow chart diagram of a method of manufacturing TFT substrate according to an embodiment of the disclosure;

FIG. 8 is a S800 flow chart diagram of a method of manufacturing TFT substrate according to an embodiment of the disclosure; and

FIG. 9 is a structural schematic view of a TFT substrate according to an embodiment of the disclosure.

### DETAILED DESCRIPTION OF PREFERRED EMBODIMENTS

In order to understand the above purposes, features and advantages of this disclosure more clearly, next, this disclosure will be described in more details with reference to the drawings and detailed description. It should be noted that in the case of not conflicting, the embodiments of the present application and the features in the embodiments can be combined with one another.

The specific structural and functional details disclosed herein are only representative and are intended for describing exemplary embodiments of the disclosure. However, the disclosure can be embodied in many forms of substitution, and should not be interpreted as merely limited to the embodiments described herein.

In addition, the following description of embodiments with reference to the attached diagram for illustrating particular embodiments may be used to embodiments of the present disclosure. Term direction of the present disclosure are mentioned, for example, “top”, “bottom”, “upper”, “lower”, “front”, “rear”, “left”, “right”, “inside”, “outside”, “side” and so on, only with reference to the accompanying drawings, direction, and thus, the direction of terms used in order to better and more clearly illustrate the present disclosure and understanding, rather than indicating device or element or imply referred to must have a specific orientation, with particular orientation construction and operation, and therefore cannot be construed as limiting the present disclosure.

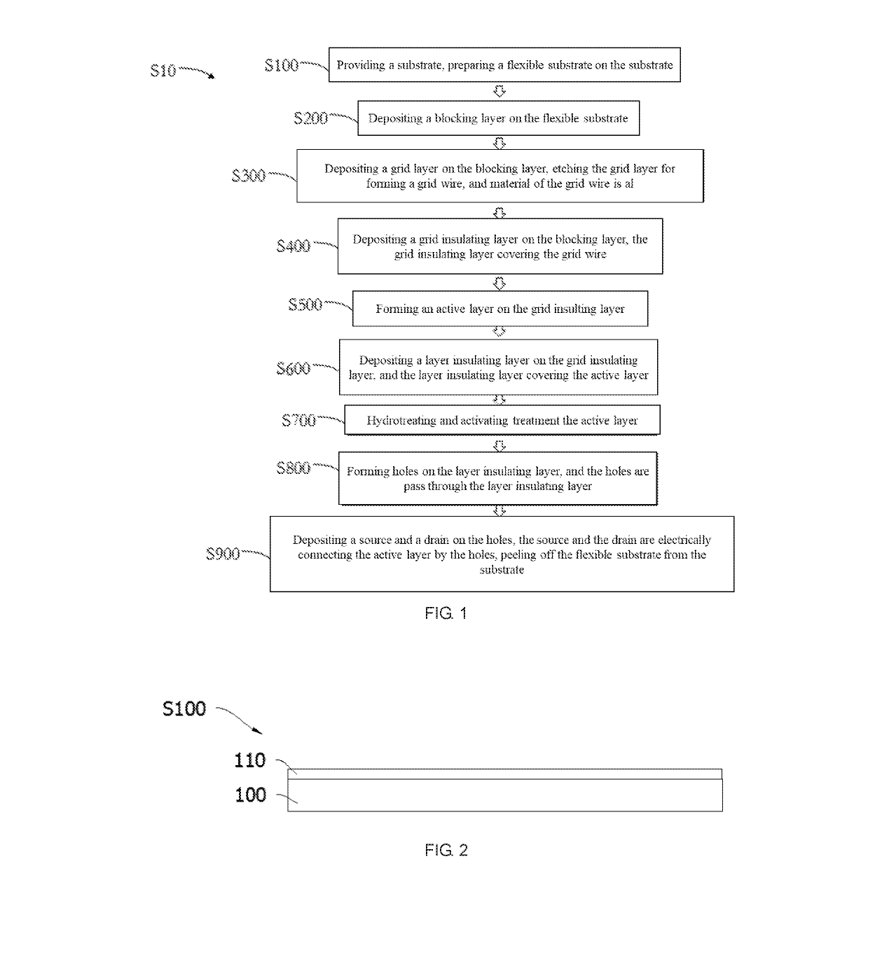

Please refer to FIG. 1, FIG. 1 is a flow chart diagram of a method of manufacturing TFT substrate according to an embodiment of the disclosure. The method is for manufacturing the flexible TFT substrate, the flexible TFT substrate is used for flexible OLED display device. Please refer to FIG. 2 through FIG. 9, the manufacturing method S10 comprising following steps.

S100, please refer to FIG. 2, providing a rigid substrate 100. Coating an organic material on the rigid substrate 100 to from a flexible substrate 110.

In this embodiment, the rigid substrate 100 could be glass substrate. Depositing the organic material on the glass substrate by Chemical Vapor Deposition (CVD), the organic material includes at least one of poly carbonate (PC), Polyethylene terephthalate (PET), poly(ethylene naphthalate) (PEN), poly(ether sulfones) (PES) and polyimide (PI). Selectively, the organic material includes polyimide (PI).

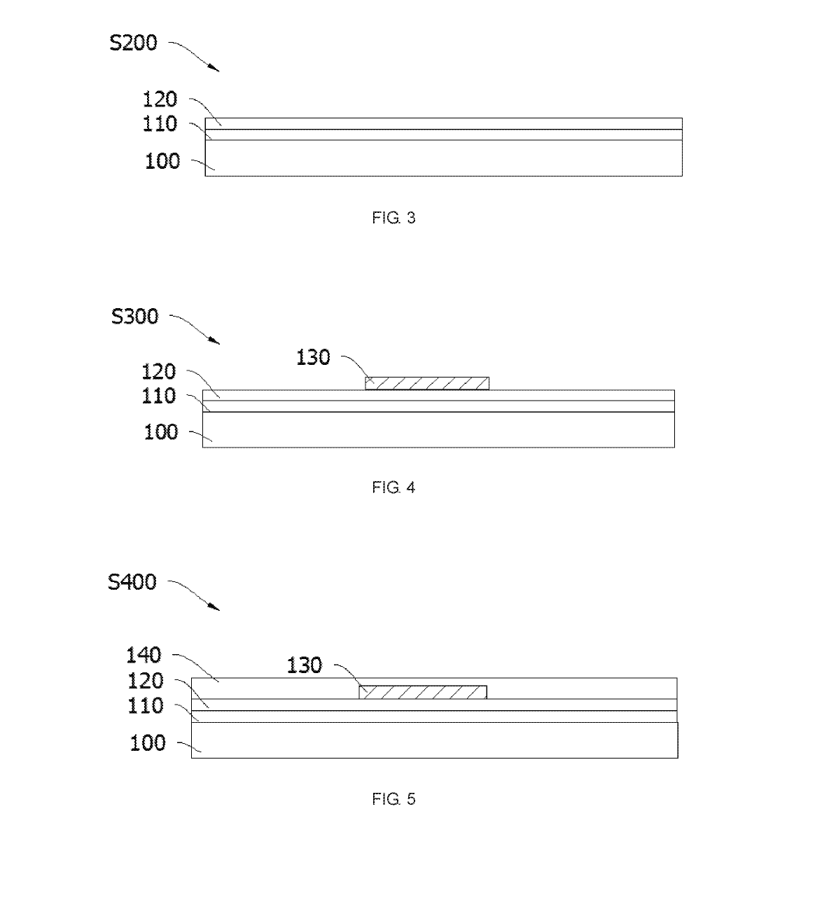

S200, please refer to FIG. 3, depositing a blocking layer 120 on the flexible substrate 110.

In this embodiment, the material of the blocking layer 120 could be at least one of SiOx, SiNx, high dielectric constant medium material and organic medium material, wherein the high dielectric constant medium material comprises aluminum oxide, hafnium oxide, zirconium oxide and so on. The deposition of the blocking layer 120 by PECVD, magnetron sputtering or reaction sputtering, atomic layer deposit or spin coating technology. The thickness of the blocking layer is 5 nm 400 nm.

In another embodiment, the blocking layer 120 is SiOx layer, SiNx layer or composite layer which stacking by SiOx layer and SiNx layer.

In another embodiment, the blocking layer 120 is heat conductive insulation layer, the material of the heat conductive insulation layer is Al₂O₃.

Further, patterning the heat conductive insulation film and obtaining the heat conductive insulation layer.

Specifically, patterning the heat conductive insulation film by photolithography and etching process, make the size and shape of the heat conductive insulation layer became the predetermined size and shape, the predetermined size and shape is for continuously manufacturing size and shape of the amorphous silicon layer.

S300, please refer to FIG. 4, depositing a grid layer on the blocking layer 120, pattering the grid layer by photolithography and etching process to from the grid wire 130. The majority material of the grid wire 130 is Al.

Selectively, depositing the grid layer on the blocking layer 120 by Physical Vapor Deposition (PVD).

Selectively, the material of the grid layer is at least one of metal, conducting metal oxide or other conductive material.

In another embodiment, the grid layer is triple-layer structure such as Ti/Al/Ti or Mo/Al/Mo.

Specifically, in the step S300 of “depositing the grid layer on the blocking layer 120”, further comprises:

S301, depositing a first Mo metal layer on the blocking layer 120, thickness of the first Mo metal layer is 30˜50 nm.

Depositing a Mo metal conducting film which has thickness of 30˜50 nm on the blocking layer 120 by magnetron sputtering. Spin coating photoresist on the Mo metal conducting film, and forming a first Mo metal layer by photolithography and etching process.

S302, depositing an Al metal layer on the first Mo metal layer. The thickness of the Al metal layer is 100˜120 nm

Depositing an Al metal conducting film which has thickness of 100˜120 nm on the first Mo metal layer by magnetron sputtering. Spin coating photoresist on the Al metal conducting film, and forming an Al metal layer by photolithography and etching process, the Al metal layer is positioned on the first Mo metal layer.

S303, depositing a second Mo metal layer on the Al metal layer, thickness of the second Mo metal layer is 30˜50 nm.

Depositing a Mo metal conducting film which has thickness of 30-50 nm on the Al metal layer by magnetron sputtering. Spin coating photoresist on the Mo metal conducting film, and forming a second Mo metal layer by photolithography and etching process. The second Mo metal layer is covering the Al metal layer.

Based on the steps above, there will forming a gird wire 130 has triple-structure Mo/Al/Mo on the blocking layer 120. The process of forming a gird wire 130 has triple-structure Ti/Al/Ti on the blocking layer 120 as same as the steps above, here is not limited thereto. The Ti or Mo of the triple structure is provided to protect Al.

Comparing with the grid wire 130 which the material is Mo metal, Al material has lower resistance, better flexible. Mo metal easy to break, impedance of the Mo metal is bigger than Al metal. In generally manufacture, the thickness of the Mo metal of the grid layer is 250 nm. In this disclosure, using the Ti/Al/Ti or Mo/A/Mo to prepare the grid layer, thickness of the Al metal layer is 100-120 nm which has same impedance of the Mo metal has thickness of 250 nm. While the Al metal and the Mo metal have same wire impedance, thickness of Al metal layer could obviously decreased; or while the Al metal and the Mo metal have same thicknesses, width of the Al metal could be tiny and achieves to high resolution display such that enhances property of bendable of grid wire 130, and prevent to break the wire, TFT element peeling, and light leakage issue during bending process of the flexible TFT substrate, and enhances quality of flexible TFT substrate, and extending lifetime of flexible TFT substrate.

S400, please refer to FIG. 5, depositing a grid insulating layer 140 on the blocking layer 120. The grid insulating layer 140 is covering the grid wire 130.

In another embodiment, depositing the grid insulating layer 140 on the blocking layer 120 and the grid wire 130. Wherein, the deposition could be PECVD, magnetron sputtering or reaction sputtering, atomic layer deposit or spin coating technology. In this embodiment, depositing the grid insulating layer 140 on the blocking layer 120 and the grid wire 130 by Chemical Vapor Deposition. Wherein, the material of the grid insulating layer 140 is at least one of SiOx, SiNx, high dielectric constant medium material and organic medium material, thickness of the grid insulating layer 140 is 5 nm˜400 nm. In this embodiment, the grid insulating layer 140 is SiOx layer, SiNx layer or composite layer which stacking by SiOx layer and SiNx layer.

S500, please refer to FIG. 6, forming an active layer 150 on the grid insulting layer 140.

In another embodiment, before forming the active layer 150, plasma processing the exposing surface of grid insulating layer 140 for increases adhering force of surface of grid insulating layer 140. In the traditional manufacturing method of the TFT substrate, there has issues of layer insulating layer be cracked or peeling during high temperature process. Therefore, in this disclosure, because the grid insulating layer 140 have been plasma processed before depositing the layer insulating layer, and enhance adhering force such that enhance adhering between the layer insulating layer and the grid insulating layer 140 and effective prevent the problem of layer insulating layer be cracked or peeling during high temperature process, and enhance product yield.

In another embodiment, in the step S500 of “forming the active layer 150 on the grid insulting layer 140”, further comprising:

S501, depositing an amorphous silicon layer on the grid insulating layer 140. The thickness of the amorphous silicon layer is 200-300 nm.

S502, treating the amorphous silicon layer by excimer laser to be heat and forming the active layer 150.

Specifically, transit the amorphous silicon layer to polycrystalline layer by Excimer Laser Annel (ELA) or Solid Phase Crystallization (SPC), and patterning the polycrystalline layer by photolithography and etching process to obtain a plurality of polycrystalline island for forming active layer 150. The mobility of polycrystalline which after the ELA process is increased, such that satisfy driving requirement.

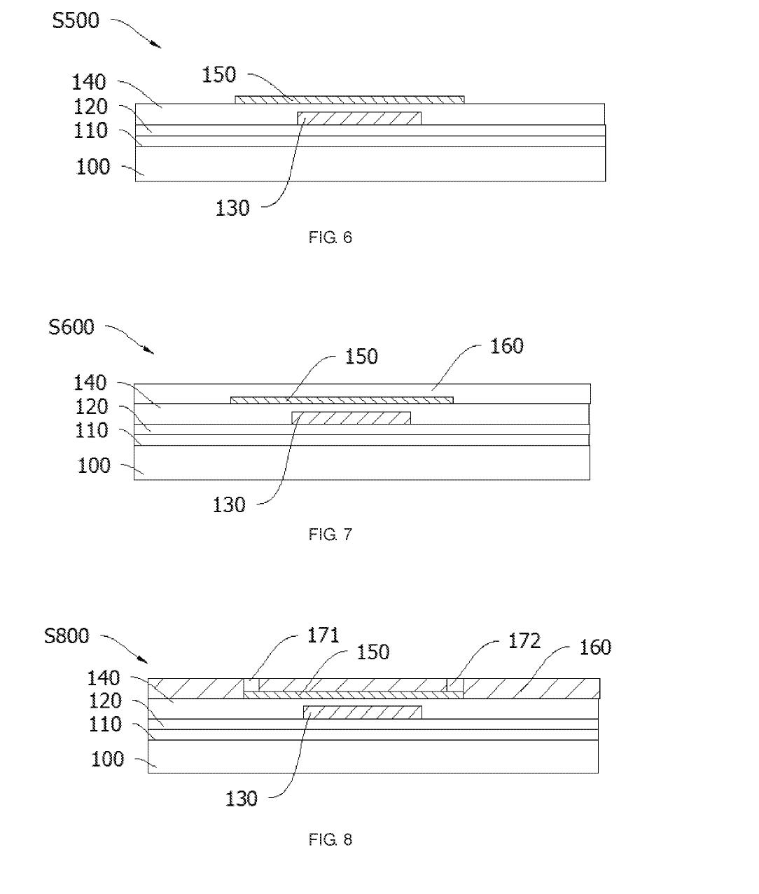

S600, please refer to FIG. 7, depositing a layer insulating layer 160 on the grid insulating layer 140 and the layer insulating layer 160 covering the active layer 150.

In another embodiment, the material of the layer insulating layer 160 is SiOx layer, SiNx layer or composite layer which stacking by SiOx layer and SiNx layer.

Specifically, depositing the layer insulating layer 160 on the grid insulating layer 140 by Chemical Vapor Deposition, and encapsulating the active layer 150 by the layer insulating layer 160. The upper surface and lower surface of the layer insulating layer 160 are directly connected to the grid insulating layer 140 and layer insulating layer 160.

S700, hydrotreating and activating treatment the active layer 150.

In another embodiment, in the step of hydrotreating and activating treatment the active layer, temperature of the hydrotreating and activating treatment is 330˜370° C., time of the hydrotreating and activating treatment is 30˜60 min.

During transit the amorphous silicon to polycrystalline, inside and surface of the polycrystalline existing defects, according to the hydrotreating and activating treatment will make the H of the layer insulating layer 160 and the grid insulating layer 140 diffuse to polycrystalline for making up defects of the polycrystalline.

In the existing technology, the layer insulating layer 160 has larger distance to the polycrystalline such that effect of the hydrotreating and activating treatment is not ideal, and easily causes electrical abnormalities of TFT element.

In this embodiment, the active layer 150 is covered between the grid insulating layer 140 and layer insulating layer 160, so that the lateral of active layer 150 are directly connecting with the grid insulating layer 140 and layer insulating layer 160. It is fever to diffuse H+ of the grid insulating layer 140 upward diffuses to the polycrystalline, and diffuse H+ of the layer insulating layer 160 downward diffuses to the polycrystalline such that enhance effects of hydrotreating and activating treatment of the active layer 150. It decreases structure defect of polycrystalline and enhance TFT performance.

Generally, hydrotreating and activating treatment the active layer 150 by the grid insulating layer 140 and layer insulating layer 160 usually needs to 450° C. and 1 hour. The material of the grid wire 130 is Al metal, and because melt point of the Al metal is lower, about 660° C. After high temperature and causes hydrotreating and activating treatment, Al metal will be membrane material changed such that decreases conductively of the grid wire 130.

In this embodiment, the upper surface and lower surface of the active layer 150 are respectively directly connecting with the grid insulating layer 140 and layer insulating layer 160, and processing hydrotreating and activating treatment. It has better activation effect so that could decrease treatment temperature to 330-370° C., which won't affect membrane material changed of the grid wire 130 and achieves to hydro-active effect at the same time.

In addition, the grid wire 130 is positioned below the active layer 150 and causes the grid wire 130 is positioned far away to the outer surface. It has small effect of oxidation or nitridation, it also decreases effect of the grid wire 130 by hydrotreating and activating treatment.

In another embodiment, the grid insulating layer 140 and the layer insulating layer 160 could be heat conductive insulation layer such as aluminum oxide layer.

In this embodiment, because the heat conductive insulation layer has better insulating property and heat conductive property, during the hydrotreating and activating treatment, the heat conductive insulation layer could fast absorb heat energy and transfer to the amorphous silicon which connected with the heat conductive insulation layer. Therefore, it enhances crystallization effective of the amorphous silicon and make the crystalline grain is bigger, the crystal boundary is less of the polycrystalline which formed in the polycrystalline layer, it makes the active layer has better electrical property such that enhance mobility of correspondingly carrier of the TFT element. It decreases the effect of leakage current by crystal boundary and improves electrical property of TFT.

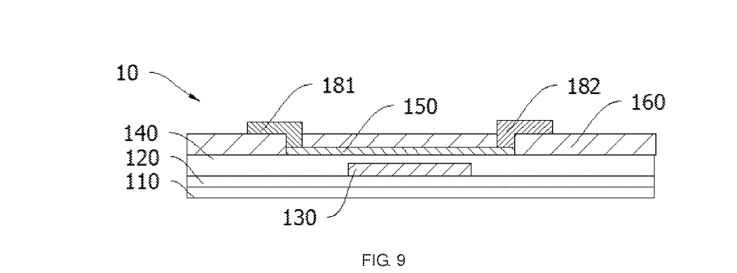

S800, please refer to FIG. 8. forming holes on the layer insulating layer 160. The holes are pass through the layer insulating layer 160.

Specifically, forming a first hole 171 and a second hole 172 by patterning the layer insulating layer 160 according to photolithography and etching process, and make the first hole 171 and the second hole 172 are electrically connecting with the active layer 150.

S900, please refer to FIG. 9, depositing a source 181 and a drain 182 on the holes, the source 181 and the drain 182 are electrically connecting with the active layer 150 by the holes. At last, peeling of the flexible substrate 110 from the rigid substrate 100 and obtaining a flexible TFT substrate.

Specifically, depositing metal layer on the first hole 171 and the second hole 172, and patterning the metal layer by photolithography and etching process to form the source 181 and the drain 182. The source 181 and the drain 182 are respectively covering the first hole 171 and the second hole 172, and connecting with the active layer 150 by the first hole 171 and the second hole 172. Peeling of the flexible substrate 110 from the rigid substrate 100, and obtains a flexible TFT substrate.

In this disclosure, according to depositing the grid wire 130 and the grid insulating layer 140 firstly, and forming active layer 150 on the grid insulating layer 140, then depositing the layer insulating layer 160 on the active layer 150, such that upper surface and lower surface of the active layer are respectively directly connecting with the grid insulating layer 140 and the layer insulating layer 160. And then, hydrotreating and activating treatment the active layer 150, because of the active layer 150 is covered by the grid insulating layer 140 and the layer insulating layer 160, such that hydrotreating and activating treatment will cause the H⁺ of the grid insulating layer 140 and the layer insulating layer 160 are diffusing to the active layer 150 from lateral side, it enhances active effect of the active layer 150 such that decreases defect of inside and surface of the active layer 150, and it enhance performance of the TFT element. In addition, because the active effect of the active layer is enhanced, it could achieve that hydrotreating and activating treatment to the active layer, and also decrease temperature of the hydrotreating and activating treatment, such that decreases conductive property effect of the grid wire 130 by temperature of hydrotreating and activating treatment, and enhances property of TFT substrate.

Please refer to FIG. 9, this disclosure further provides a TFT substrate 10 for manufacturing the flexible OLED display device. The TFT substrate 10 is made by TFT substrate manufacturing method S10 described according to any embodiments above. The TFT substrate 10 includes a flexible substrate 110, a blocking layer 120 is positioned on the flexible substrate 110, a grid wire 130 is positioned on the blocking layer 120, a grid insulating layer 140 is covering the grid wire 130, an active layer 150 is positioned on the grid insulating layer 140, and a layer insulating layer 160 is covering the active layer 150. The material of the grid wire is Al. In another embodiment, the grid layer is triple structure such as Ti/Al/Ti or Mo/Al/Mo. The Ti or Mo of the triple structure is for protecting the Al.

Comparing with the grid wire 130 which made by Mo metal, the Al metal has lower resistance and better flexibility. While the Al metal and the Mo metal has same wire impedance, the thickness of the Al metal is obviously decreased; or while the Al metal and the Mo metal has same thickness, the width of Al metal wire is small and also could achieve to high resolution display such that enhances property of bendable of the grid wire 130.

In another embodiment, the TFT substrate 10 further comprising holes 171, 172 are passing through the layer insulating layer 160, and the source 181 and the drain 182 are positioned on the holes 171, 172. The source 181 and the drain 182 are electrically connecting with the active layer 150 by the holes 171, 172.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A method of manufacturing TFT substrate, the method comprising
providing a substrate, preparing a flexible substrate on the substrate;
depositing a blocking layer on the flexible substrate;
depositing a grid layer on the blocking layer, etching the grid layer for forming a grid wire, and material of the grid wire is Al;
depositing a grid insulating layer on the blocking layer, the grid insulating layer covering the grid wire;
forming an active layer on the grid insulting layer;
depositing a layer insulating layer on the grid insulating layer, and the layer insulating layer covering the active layer;
hydrotreating and activating treatment the active layer.

2. The method of manufacturing TFT substrate according to claim 1, wherein the grid layer is triple-layer structure, Ti/Al/Ti or Mo/Al/Mo.

3. The method of manufacturing TFT substrate according to claim 2, wherein in the step of depositing the grid layer on the blocking layer further comprising
depositing a first Mo metal layer on the blocking layer, thickness of the first Mo metal layer is 30˜50 nm;
depositing an Al metal layer on the first Mo metal layer, thickness of the Al metal layer is 100˜120 nm;
depositing a second Mo metal layer on the Al metal layer, thickness of the second Mo metal layer is 30˜50 nm.

4. The method of manufacturing TFT substrate according to claim 1, wherein in the step of hydrotreating and activating treatment the active layer, temperature of the hydrotreating and activating treatment is 330˜370° C., time of the hydrotreating and activating treatment is 30˜60 min.

5. The method of manufacturing TFT substrate according to claim 1, wherein after the step of hydrotreating and activating treatment the active layer, further comprising
forming holes on the layer insulating layer, and the holes are pass through the layer insulating layer;
depositing a source and a drain on the holes, the source and the drain are electrically connecting the active layer by the holes;
peeling off the flexible substrate from the substrate.

6. The method of manufacturing TFT substrate according to claim 1, wherein in the step of forming the active layer on the grid insulting layer, further comprising
depositing an amorphous silicon layer on the grid insulating layer,
treating the amorphous silicon layer by excimer laser to be heat source and forming the active layer.

7. The method of manufacturing TFT substrate according to claim 1, wherein material of the grid insulating layer and layer insulating layer are SiOx or SiNx or stacked structure of SiOx and SiNx.

8. The method of manufacturing TFT substrate according to claim 1, wherein the blocking layer is heat conductive insulation layer.

9. A TFT substrate, the TFT substrate comprising
a flexible substrate;
a blocking layer on the flexible substrate;
a grid wire on the blocking layer,
a grid insulating layer covering the grid wire;
an active layer on the grid insulating layer, and
a layer insulating layer covering the active layer.

10. The TFT substrate according to claim 9, wherein the TFT substrate further comprises
holes for passing through the layer insulating layer,
a source and a drain are positioned on the holes, the source and the drain are electrically connecting to the active layer by the holes.
